(19) United States
(12) Patent Application Publication
(10) Pub. No.: US 2010/0175744 A1
(43) Pub. Date: Jul. 15, 2010

(54) DIFFUSING AGENT COMPOSITION, METHOD OF FORMING IMPURITY DIFFUSION LAYER, AND SOLAR BATTERY

(75) Inventors: Takaaki Hirai, Kawasaki-shi (JP); Katsuya Tanitsu, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 12/651,948

(22) Filed: Jan. 4, 2010

(30) Foreign Application Priority Data
Jan. 9, 2009 (JP) 2009-004036

(51) Int. Cl. H01L 31/02; H01L 21/228; C08L 29/04; C08K 3/38; C08K 3/22

(52) U.S. Cl. 136/252; 438/542; 524/557; 524/405; 524/430; 257/E21.153

(57) ABSTRACT

A diffusing agent composition is used for ink-jet printing and contains a P-type impurity-diffusing component (A), a water-soluble polymer compound (B) having an alcoholic hydroxyl group, and a solvent (C) containing an organic solvent having a surface tension of at most about 30 mN/m.

### BACKGROUND OF THE INVENTION

1. Field of the Invention

The present invention relates to a diffusing agent composition, a method of forming an impurity diffusion layer, and a solar battery.

2. Description of the Related Art

In the related art, in the case of, for example, forming a P-type impurity diffusion layer in a semiconductor substrate in manufacturing a solar battery, the P-type impurity diffusion layer is formed by patterning a diffusing agent containing a P-type impurity-diffusing component on a surface of the semiconductor substrate followed by diffusing the P-type impurity-diffusing component from the patterned diffusing agent. More specifically, a thermally-oxidized film is formed on a surface of the semiconductor substrate, and a resist having a predetermined pattern is then laminated on the thermally-oxidized film by a photolithography method. Using the resist as a mask, the thermally-oxidized film that is not masked by the resist is etched with acid or alkali, and the resist is then peeled off so as to form a mask of a thermally-oxidized film. A P-type impurity diffusion layer is then formed in a semiconductor substrate by applying a diffusing agent so as to form a diffusion film on a mask opening part, followed by diffusing an impurity-diffusing component contained in the diffusing agent.

As described above, many processes are required for forming an impurity diffusion layer within a semiconductor substrate in the related art. For example, JP Laid-Open Publication Nos. 2003-168810, 2003-332606, and 2006-156646 disclose a method of patterning diffusing agents on a surface of a semiconductor substrate by using an ink-jet method at the same time. An ink-jet method does not require a complicated process compared to a conventional photolithography method, etc., since patterning is performed by discharging a diffusing agent on the forming region of a P-type impurity diffusion layer from an ink-jet nozzle without using a mask, thus allowing a pattern to be easily formed.

In the above-described patterning method where an ink-jet method is used, a high-viscosity diffusing agent, when used, makes the clogging of an ink-jet nozzle more likely, which lowers the discharge stability. On the other hand, when the viscosity of the diffusing agent is lowered for improved discharge stability, there is a possibility that the diffusing agent that has landed on a semiconductor substrate is spread over the semiconductor substrate in such a manner that a pattern formed by the applied diffusing agent becomes indistinct over time, lowering the printing performance.

When the surface tension of a diffusing agent to be used is large, the pressure that is necessary for discharging the diffusing agent from an ink-jet nozzle and that is to be applied to the diffusing agent becomes large, lowering the discharge stability. Furthermore, the diffusing agent that has landed on a semiconductor substrate shrinks on the semiconductor substrate and produces unevenness in printing (i.e., cratering, cissing, and repelling), lowering the printing performance. On the other hand, when the surface tension of the diffusing agent is lowered for improved discharge stability and for suppressed crater production, there is a possibility that the diffusing agent that has landed on a semiconductor substrate is spread over the semiconductor substrate in such a manner that the pattern formed by the applied diffusing agent becomes indistinct over time, lowering the printing performance.

### SUMMARY OF THE INVENTION

In this background, one of purposes of the present invention is to provide a diffusing agent composition for ink-jet printing having a higher discharge stability and printing performance, a method of forming an impurity diffusion layer using the diffusing agent composition, and a solar battery.

An embodiment of the present invention relates to a diffusing agent composition, and the diffusing agent composition is used for ink jet printing and comprises: a P-type impurity-diffusing component (A); a water-soluble polymer compound (B) having an alcoholic hydroxyl group; and a solvent (C) containing an organic solvent having a surface tension of at most about 30 mN/m.

According to the present embodiment, a diffusing agent composition for ink-jet printing having a higher discharge stability and printing performance can be obtained.

Another embodiment of the present invention relates to a method of forming an impurity diffusion layer, and the method of forming an impurity diffusion layer comprises: forming a pattern by discharging the diffusing agent composition according to the above embodiment containing a P-type impurity-diffusing component (A) onto an N-type semiconductor substrate by an ink-jet method; and diffusing the impurity-diffusing component (A) contained in the diffusing agent composition into the semiconductor substrate.

According to the embodiment, an impurity diffusion layer can be formed with higher accuracy.

Yet another embodiment of the present invention relates to a solar battery. The solar battery comprises a semiconductor substrate in which an impurity diffusion layer is formed by the method of forming an impurity diffusion layer of the embodiment.

According to the embodiment, a more reliable solar battery can be obtained.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIGS. 1A-1E are process sectional views illustrating a method of manufacturing a solar battery including a method of forming an impurity diffusion layer according to an embodiment 1.

### DETAILED DESCRIPTION OF THE INVENTION

The invention will now be described by reference to the preferred embodiments. This does not intend to limit the scope of the present invention, but to exemplify the invention.

Described below is an explanation with reference to figures, based on the preferred embodiments of the present invention. Like reference characters designate like or corresponding elements, members and processes throughout the views. The description of them will not be repeated for brevity. Reference herein to details of the illustrated embodiments is not intended to limit the scope of the claims. It should be understood that not all of the features and the combination thereof discussed are essential to the invention.

### Embodiment

The diffusing agent composition according to the embodiment is used for ink-jet printing and contains an impurity-diffusing component (A), a water-soluble polymer compound (B), and a solvent (C). Each component of the diffusing agent composition of the embodiment is described in detail in the following.

<<Impurity-Diffusing Component (A)>>

The impurity-diffusing component (A) is a compound generally used as a dopant for manufacturing a solar battery. The impurity-diffusing component (A) is, for example, a P-type impurity-diffusing component containing a compound of a group III element, and a P-type impurity diffusion layer (impurity diffusion region) can thus be formed in an N-type semiconductor substrate in a process of forming an electrode of a solar battery. Examples of the compound of a group III element contained in the impurity-diffusing component (A) include B₂O₃, Al₂O₃, or the like, and the impurity-diffusing component (A) contains at least one kind of these compounds. The concentration of the impurity-diffusing component (A) is appropriately adjusted in accordance with, for example, the thickness of the impurity diffusion layer formed on the semiconductor substrate.

<<Water-Soluble Polymer Component (B)>>

The water-soluble polymer compound (B) is a water-soluble polymer compound having a hydroxyl group, in particular, an alcoholic hydroxyl group. The water-soluble polymer compound (B) has a function of dispersing the impurity-diffusing component (A) into water acting as a solvent. Specific examples of the water-soluble polymer compound (B) include, for example, polyvinyl alcohol. The water-soluble polymer compound (B) such as polyvinyl alcohol contained in a diffusing agent composition suppresses the increase in viscosity of the diffusing agent composition, allowing air bubbles trapped in the diffusing agent composition to be easily removed, that is, allowing the defoamability to be improved. This allows the discharge stability of the diffusing agent composition to be improved. Preferably, the water-soluble polymer compound (B) has a saponification degree of at least 90 mol %. In this case, the diffusivity of the diffusing agent composition on a semiconductor substrate can be improved.

<<Solvent (C)>>

The solvent (C) contains an organic solvent having a surface tension of at most about 30 mN/m at a reference temperature of 20 degrees centigrade. Examples of the organic solvent having a surface tension of at most about 30 mN/m include methanol. The surface tension of methanol at the reference temperature of 20 degrees centigrade is about 22.6 mN/m. The solvent (C) preferably contains the organic solvent having a surface tension of at most about 30 mN/m with a weight percent of at least about 30 percent based on the total weight of the composition. When the solvent (C) contains the organic solvent having a surface tension of at most about 30 mN/m with a weight percent of at least about 30 percent based on the total weight of the composition, the surface tension of the diffusing agent composition can be lowered. This allows the printing performance of the diffusing agent composition to be improved.

The solvent (C) may contain an organic solvent having a viscosity of at most about five cP. An example of an organic solvent having a viscosity of at most about five cP includes methanol. The solvent (C) preferably contains the organic solvent having a viscosity of at most about five cP with a weight percent of at least about 30 percent based on the total weight of the diffusing agent composition. When the solvent (C) contains the organic solvent having a viscosity of at most about five cP with a weight percent of at least about 30 percent based on the total weight of the diffusing agent composition, the increase in the viscosity of the diffusing agent composition is suppressed, allowing the defoamability to be improved. This allows the discharge stability of the diffusing agent composition to be improved.

The solvent (C) may contain a high-boiling solvent having a boiling point of at least about 180 degrees centigrade. An example of a high-boiling solvent having a boiling point of at least about 180 degrees centigrade includes triethylene glycol monomethyl ether (TGME). The solvent (C) preferably contains the high-boiling solvent having a boiling point of at least about 180 degrees centigrade with a weight percent of at most about 30 percent based on the total weight of the diffusing agent composition. When the solvent (C) contains the high-boiling solvent having a boiling point of at least about 180 degrees centigrade with a weight percent of at most about 30 percent based on the total weight of the diffusing agent composition, the drying characteristics of the diffusing agent composition can be lowered. Lowering the drying characteristics of the diffusing agent composition can prevent the clogging of an ink-jet nozzle, which is produced when the diffusing agent composition dries. As a result, the discharge stability of the diffusing agent composition is improved.

Furthermore, the solvent (C) may contain dipropylene glycol. When the solvent (C) contains dipropylene glycol, both the surface tension and viscosity of the diffusing agent composition can be increased.

In the diffusing agent composition according to the embodiment, the total contained amount of the impurity-diffusing component (A) and water-soluble polymer compound (B) is preferably in a range of about 1-10 weight percent based on the total weight of the diffusing agent composition. A diffusing agent composition containing the impurity-diffusing component (A) and the water-soluble polymer compound (B) in a total contained amount outside of the above specified range can still be used. However, when the total contained amount of the impurity-diffusing component (A) and water-soluble polymer compound (B) is less than about one weight percent based on the total weight of the diffusing agent composition, the diffusing agent that has landed on a semiconductor substrate is easily spread over the semiconductor substrate, lowering the printing performance. On the other hand, when the total contained amount of the impurity-diffusing component (A) and water-soluble polymer compound (B) is more than about 10 weight percent based on the total weight of the diffusing agent composition, this easily produces clogs in an ink-jet nozzle, lowering the discharge stability.

The contained amount of the solvent (C) is preferably in a range of about 90-99 weight percent based on the total weight of the diffusing agent composition. A diffusing agent composition containing the solvent (C) in a contained amount outside of the above specified range can still be used. However, when the contained amount of the solvent (C) is less than about 90 weight percent based on the total weight of the diffusing agent composition, this easily produces clogs in an ink-jet nozzle, lowering the discharge stability. On the other hand, when the contained amount of the solvent (C) is more than about 99 weight percent based on the total weight of the diffusing agent composition, the diffusing agent that has landed on a semiconductor substrate is easily spread over the semiconductor substrate, lowering the printing performance.

The diffusing agent composition may further contain a water-soluble monomer (D) having a hydroxyl group. Containing the water-soluble monomer (D) allows the diffusivity of the impurity-diffusing component (A) in the diffusing agent composition to be improved. An example of the water-soluble monomer (D) having a hydroxyl group includes mannitol (mannite) having six hydroxyl groups.

The viscosity of the diffusing agent composition at the time of discharge from an ink-jet head is preferably at most about 10 cP. The concentration of a metallic impurity contained in the diffusing agent composition is preferably at most about 500 ppm. This can suppress a decrease in the efficiency of the photovoltaic effect produced by the inclusion of the metallic impurity. The diffusing agent composition of the embodiment may contain a commonly-used surface-active agent, antifoaming agent, or the like as another additive agent.

<<Method of Forming Impurity Diffusion Layer and Method of Manufacturing Solar Battery>>

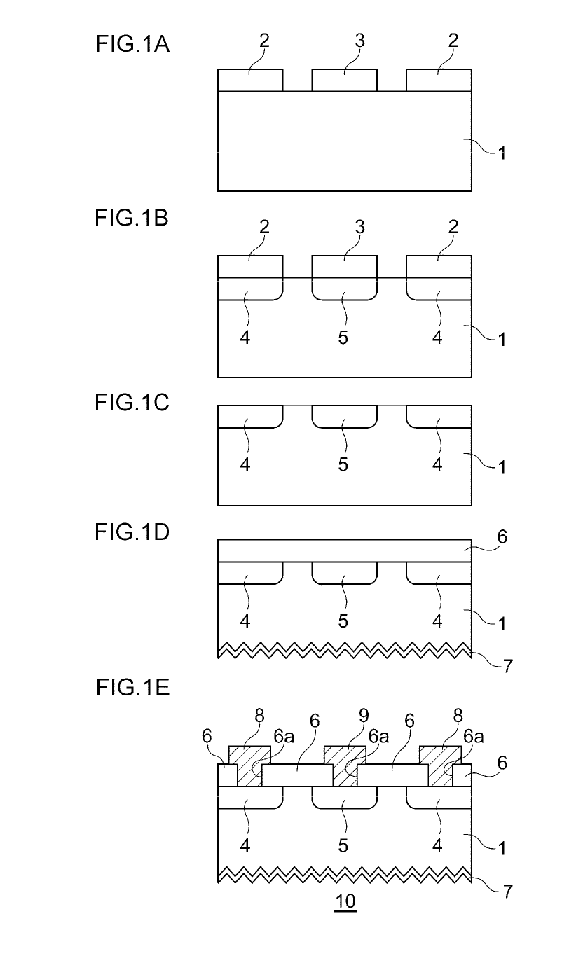

In reference to FIGS. 1A-1E, a detailed description will be made regarding a method of forming an impurity diffusion layer comprising a step of forming a pattern by discharging the above-stated diffusing agent composition containing a P-type impurity-diffusing component (A) onto an N-type semiconductor substrate by an ink-jet method and a step of diffusing the impurity-diffusing component (A) contained in the diffusing agent composition into the semiconductor substrate, and regarding a method of manufacturing a solar battery provided with a semiconductor substrate in which the impurity diffusion layer is formed by the method of forming an impurity diffusion layer. FIGS. 1A-1E are process sectional views for explaining the method of manufacturing a solar battery including the method of forming the impurity diffusion layer according to the embodiment 1.

As shown in FIG. 1A, a diffusing agent composition 2 containing a P-type impurity-diffusing component (A) as described above and a diffusing agent composition 3 containing an N-type impurity-diffusing component are applied onto an N-type semiconductor substrate 1 such as a silicon substrate in a selective manner. The diffusing agent composition 3 containing an N-type impurity-diffusing component is a diffusing agent composition adjusted by a well-known method. The diffusing agent composition 3 is, for example, applied onto the entire surface of the semiconductor substrate 1 by a well-known method such as the spin-coating method, and the applied diffusing agent composition 3 is then dried by using a well-known means such as an oven. Then, the diffusing agent composition 3 is selectively removed by a well-known photolithography method and etching method so as to form a pattern. A pattern may be formed by selectively applying the diffusing agent composition 3 onto the surface of the semiconductor substrate 1 by an ink-jet method.

The diffusing agent composition 2 is formed into a pattern by being selectively applied onto the surface of the semiconductor substrate 1 by an ink-jet method. In other words, patterning is carried out by discharging the diffusing agent composition 2 from an ink-jet nozzle of a well-known ink-jet dispenser onto a forming region of a P-type impurity diffusion layer of the semiconductor substrate 1. After the patterning, the applied diffusing agent composition 2 is dried by using a well-known means such as an oven. A piezoelectric dispenser using a piezoelectric element that deforms when a voltage is applied is used as an ink-jet dispenser. A thermal dispenser using bubbles produced by heating may also be used.

As shown in FIG. 1B, the semiconductor substrate 1 on which the diffusing agent composition 2 and the diffusing agent composition 3 are patterned is placed inside, for example, a diffusion furnace such as an electric furnace and is burned so that the P-type impurity-diffusing component (A) in the diffusing agent composition 2 and the N-type impurity-diffusing component in the diffusing agent composition 3 diffuse into the semiconductor substrate through the surface of the semiconductor substrate 1. Instead of a diffusion furnace, the semiconductor substrate 1 may be heated by commonly-used laser irradiation. In this manner, the P-type impurity-diffusing component (A) diffuses into the semiconductor substrate 1, forming a P-type impurity diffusion layer 4. The N-type impurity-diffusing component diffuses into the semiconductor substrate 1, forming an N-type impurity diffusion layer 5.

As shown in FIG. 1C, the diffusing agent composition 2 and the diffusing agent composition 3 are then removed by a well-known etching method.

As shown in FIG. 1D, a passivation layer 6 is formed on the surface of the semiconductor substrate 1 on the side where the P-type impurity diffusion layer 4 and the N-type impurity diffusion layer 5 are formed. On the side of the semiconductor substrate 1 on the side opposite from the side where the passivation layer 6 is formed, a texture structure having a fine relief structure is formed by a well-known method. A silicon nitride film 7 having an anti-sunlight reflection effect is formed over the texture structure.

As shown in FIG. 1E, the passivation layer 6 is selectively removed by a well-known photolithography method and etching method so that contact holes 6a are formed in such a manner that predetermined regions of the P-type impurity diffusion layer 4 and N-type impurity diffusion layer 5 are exposed. A desired metal is filled in the contact hole 6a provided above the P-type impurity diffusion layer 4 by, for example, electrolytic plating and electroless plating so as to form an electrode 8 that is electrically connected with the P-type impurity diffusion layer 4. Similarly, an electrode 9 that is electrically connected with the N-type impurity diffusion layer 5 is formed in the contact hole 6a provided above the N-type impurity diffusion layer 5. These steps allows for manufacturing a solar battery 10 according to the embodiment.

In summing up the above-explained functions and effects of the diffusing agent composition according to the embodiment, the diffusing agent composition according to the embodiment contains the P-type impurity-diffusing component (A), the water-soluble polymer compound (B) having an alcoholic hydroxyl group, and the solvent (C) containing an organic solvent having a surface tension of at most about 30 mN/m. This can provide a diffusing agent composition for an ink-jet method with more improved discharge stability and printing performance. The use of the diffusing agent composition allows for more accurate pattern formation, improving the reliability of a solar battery.

Using the water-soluble polymer compound (B) having a saponification degree of at least about 90 mol % and using polyvinyl alcohol as the water-soluble polymer compound (B) can further improve the discharge stability and printing performance. Containing the organic solvent having a surface tension of at most about 30 mN/m with a weight percent of at least about 30 percent based on the total weight of the composition can further improve the printing performance.

When the diffusing agent composition contains a high-boiling solvent having a boiling point of at least about 180 degrees centigrade, the drying characteristics of the diffusing agent composition can be lowered. This can prevent clogging of an ink-jet nozzle, which is produced when the diffusing agent composition dries, and thus can improve the discharge stability.

Ink-jet printing is used in the method of forming an impurity diffusion layer and the method of manufacturing a solar battery. Thus, an impurity diffusion region can be selectively provided at a desired position. Therefore, in comparison to a conventional method, consumption of the diffusing agent composition can be suppressed, while no complicated step is required. This can reduce manufacturing cost of a solar battery.

The embodiment is intended to be illustrative only, and it will be obvious to those skilled in the art that various modifications could be developed based on the knowledge of a skilled person and that such modifications are also within the scope of the present invention.

For example, the impurity-diffusing component (A) is a P-type impurity-diffusing component containing a compound of a group III element in the above embodiment; however, the impurity-diffusing component (A) may be an N-type impurity-diffusing component containing a compound of a group V element. Examples of a component containing a compound of a group V element include P₂O₅ and the like.

### Exemplary Embodiments

The invention will now be described by reference to the preferred exemplary embodiments. This does not intend to limit the scope of the present invention, but to exemplify the invention.

### Diffusing Agent Composition

### Exemplary Embodiments 1-7

In accordance with the components and content ratios described in the following Table 1, polyvinyl alcohol acting as the water-soluble polymer compound (B) is dissolved in water, and propylene glycol monomethyl ether (PGME) and N-methylpyrrolidone (NMP) are then added and dissolved. Powdered B₂O₃ is then added, acting as the impurity-diffusing component (A). The mixture is heated to about 80 degrees centigrade and agitated for about one hour. The mixture is then cooled down and diluted by adding the solvent (C). A diffusing agent composition (P-type dopant solution) for ink-jet printing is obtained as a result. Polyvinyl alcohol having a polymerization degree of about 300 is used in the exemplary embodiments 1-4, 6, and 7, and polyvinyl alcohol having a polymerization degree of about 600 is used in the exemplary embodiment 5. The exemplary embodiment 4 represents an exemplary embodiment where the diffusing agent composition contains a water-soluble monomer (D), the exemplary embodiment 6 represents an exemplary embodiment where the saponification degree of the soluble polymer compound (B) is less than about 90 mol %, and the exemplary embodiment 7 represents an exemplary embodiment where the solvent (C1) having a surface tension of at most about 30 mN/m accounts for less than about 30 weight percent.

### Comparative Examples 1-3

In accordance with the components and content ratios described in the following Table 2, a diffusing agent composition (P-type dopant solution) for ink-jet printing is obtained in a similar manner as in the exemplary embodiments 1-7. Polyvinyl alcohol having a polymerization degree of about 300 is used in the comparative examples 2 and 3.

In the comparative example 1, a diffusing agent composition is obtained having the same composition as that of the exemplary embodiment 1 except that the polyvinyl alcohol acting as the water-soluble polymer compound (B) is replaced with polyallylamine, which does not have an alcoholic hydroxyl group. In other words, the comparative example 1 is a diffusing agent composition that does not contain the a water-soluble polymer compound (B).

In the comparative example 2, a diffusing agent composition is obtained having the same composition as that of the exemplary embodiment 1 except that the solvent (C1) and the solvent (2) are replaced with water. In other words, the comparative example 2 is a diffusing agent composition that does not contain the solvent (C). The surface tension of water at the reference temperature of 20 degrees centigrade is about 72.75 mN/m.

In the comparative example 3, a diffusing agent composition is obtained having the same composition as that of the exemplary embodiment 1 except that the solvent (C1), which is an organic solvent having a surface tension of at most about 30 mN/m, is replaced with water and that the contained amount of the solvent (C2) having a surface tension of more than about 30 mN/m at the reference temperature of 20 degrees centigrade is changed from about 26.2 weight percent to about 49.8 weight percent. In other words, the comparative example 3 is a diffusing agent composition that does not contain the organic solvent having a surface tension of at most about 30 mN/m. The surface tension of TGME at the reference temperature of 20 degrees centigrade is about 35.9 mN/m.

TABLE 1

| EXEMPLARY EMBODIMENT | | 1 | 2 | 3 | 4 | 5 | 6 | 7 |
|---|---|---|---|---|---|---|---|---|
| SOLUBLE | SAPONIFICATION | 98.5 mol % | 98.5 mol % | 98.5 mol % | 98.5 mol % | 91 mol % | 88 mol % | 98.5 mol % |
| POLYMER | DEGREE | | | | | | | |
| COMPOUND | CONTANED | 2.0 wt % | 2.0 wt % | 4.2 wt % | 1.4 wt % | 2.0 wt % | 2.0 wt % | 2.0 wt % |
| (B) | AMOUNT | | | | | | | |
| POLYALLYLAMINE | | — | — | — | — | — | — | — |
| WATER | | 10.4 wt % | 10.4 wt % | 21.7 wt % | 6.0 wt % | 10.4 wt % | 10.4 wt % | 60.2 wt % |
| WATER-SOLUBLE MONOMER | | — | — | — | 0.3 wt % | — | — | — |
| (D) | | | | | | | | |
| PGME | | 12.6 wt % | 12.6 wt % | 26.3 wt % | 8.9 wt % | 12.6 wt % | 12.6 wt % | 12.6 wt % |
| NMP | | 8.4 wt % | 8.4 wt % | 17.1 wt % | 5.9 wt % | 8.4 wt % | 8.4 wt % | 8.4 wt % |
| IMPURITY-DIFFUSING | | 0.4 wt % | 0.4 wt % | 0.8 wt % | 0.7 wt % | 0.4 wt % | 0.4 wt % | 0.4 wt % |
| COMPONENT (A) | | | | | | | | |
| SOLVENT (C) | SOLVENT (C1) | 40 wt % | 46.4 wt % | 30.0 wt % | 61.7 wt % | 40 wt % | 40 wt % | 16.4 wt % |
| | SOLVENT (C2) | 26.2 wt % | 19.8 wt % | — | 12.1 wt % | 26.2 wt % | 26.2 wt % | — |
| | SOLVENT (C3) | — | — | — | 3.0 wt % | — | — | — |

| | | | | | | | |
|---|---|---|---|---|---|---|---|
| DISCHARGE STABILITY | A | A | A | A | A | A | A |
| PRINTING PERFORMANCE | AA | AA | AA | AA | AA | AA | A |
| DIFFUSIVITY | AA | AA | AA | AAA | AA | A | AA |

TABLE 2

| | | COMPARATIVE EXAMPLE | | |
|---|---|---|---|---|
| | | 1 | 2 | 3 |
| SOLUBLE POLYMER | SAPONIFICATION | — | 98.5 mol % | 98.5 mol % |
| COMPOUND (B) | DEGREE | | | |
| | CONTAINED | — | 2.0 wt % | 2.0 wt % |
| | AMOUNT | | | |

| POLYALLYLAMINE | | 2.0 wt % | — | — |
|---|---|---|---|---|
| WATER | | 10.4 wt % | 76.6 wt % | 26.8 wt % |
| WATER-SOLUBLE MONOMER (D) | | — | — | — |
| PGME | | 12.6 wt % | 12.6 wt % | 12.6 wt % |
| NMP | | 8.4 wt % | 8.4 wt % | 8.4 wt % |
| IMPURITY-DIFFUSING COMPONENT (A) | | 0.4 wt % | 0.4 wt % | 0.4 wt % |
| SOLVENT (C) | SOLVENT (C1) | 40 wt % | — | — |
| | SOLVENT (C2) | 26.2 wt % | — | 49.8 wt % |
| | SOLVENT (C3) | — | — | — |

| | | | |
|---|---|---|---|
| DISCHARGE STABILITY | B | B | B |
| PRINTING PERFORMANCE | B | B | B |
| DIFFUSIVITY | B | A | A |

NOTE:
Impurity-Diffusing Component (A): B₂O₃
Water-Soluble Polymer Compound (B): Polyvinyl Alcohol
Solvent (C)
Solvent (C1): Methanol
Solvent (C2): Triethylene Glycol Monomethyl Ether (TGME)
Solvent (C3): Dipropylene Glycol
Water-Soluble Monomer (D): Mannitol

The solvent (C1) corresponds to an organic solvent having a surface tension of at most about 30 mN/m, and the solvent (C2) corresponds to a high-boiling solvent having a boiling point of at least about 180 degrees centigrade.

### Patterning of Diffusing Agent Composition

### Exemplary Embodiments 1-7

### Comparative Examples 1-3

A pattern having a predetermined shape is formed by discharging each of the diffusing agent compositions obtained as described above onto the surface of a semiconductor substrate by using a piezoelectric ink-jet dispenser. This process is repeated for three times.

(Evaluation of Diffusing Agent Composition)

Each pattern is visually observed. When no chasm is produced, in other words, no cracking is produced in any of the formed patterns, the discharge stability is determined to be A. When a cracking is produced in any of the formed patterns, the discharge stability is determined to be B.

Furthermore, the patterns formed with no cracking are left to stand and are then visually observed for unevenness in printing (i.e., cratering) produced by the shrinkage of the diffusing agent composition on the semiconductor substrate. When no cratering is produced in any of the formed patterns, the printing performance is determined to be AA. When a crater that does not affect the formation of an impurity diffusion layer is produced, the printing performance is determined to be A. When a crater that can affect the formation of an impurity diffusion layer is produced, the printing performance is determined to be B. The “crater that can affect the formation of an impurity diffusion layer” can be determined by a skilled person in the art based on experiments, etc.

A P-type diffusion layer is formed by using each diffusing agent composition in accordance with the method of forming an impurity diffusion layer, and the diffusivity of the each diffusing agent composition is evaluated by measuring the sheet resistance of the P-type diffusion layer. In the step of forming the P-type diffusion layer, the diffusion of a pattern formed on a semiconductor substrate is performed for about 30 minutes at about 600 degrees centigrade under oxygen atmosphere and for about 30 minutes at about 1000 degrees centigrade under nitrogen atmosphere. The measurement of the sheet resistance is carried out by using a sheet resistance meter VR-70 (manufactured by Hitachi Kokusai Denki Engineering Co., Ltd.). The diffusivity is evaluated to be: AAA when the sheet resistance (Ω/sq.) is less than about 60; AA when the sheet resistance is at least about 60 but less than about 80; A when the sheet resistance is at least about 80 but less than about 100; and B when the sheet resistance is at least about 100.

With regard to the properties, discharge stability, printing performance, and diffusivity, the evaluation is displayed in such a manner that A indicates “good” and B indicates “bad.” A greater number of A′s indicates better properties.

As a result, the discharge stability, the printing performance, and the diffusivity are all found to be “good” (A-AAA) in all the exemplary embodiments. In the comparative example 1, the discharge stability, the printing performance, and the diffusivity are all found to be “bad” (B). In the comparative examples 2 and 3, the diffusivity is found to be “good” (A); however, the discharge stability and the printing performance are found to be “bad” (B).

The comparison of exemplary embodiments 1-7 with the comparative examples 1-3 teaches that good discharge stability, printing performance, and diffusivity can be obtained when a diffusing agent composition contains a water-soluble polymer compound (B) and a solvent (C) containing an organic solvent having a surface tension of at most about 30 mN/m. The comparison of exemplary embodiment 6 with other exemplary examples teaches that even better diffusivity can be obtained when a water-soluble polymer compound (B) has a saponification degree of at least about 90 mol %. The comparison of exemplary embodiment 4 with other exemplary examples teaches that further better diffusivity can be obtained when a diffusing agent composition contains a water-soluble monomer (D). Furthermore, the comparison of exemplary embodiment 7 with other exemplary examples teaches that an even better printing performance can be obtained when the solvent (C) contains an organic solvent having a surface tension of at most about 30 mN/m with a weight percent of at least about 30 percent based on the total weight of the composition.

What is claimed is:

1. A diffusing agent composition used for ink-jet printing comprising:
a P-type impurity-diffusing component (A);
a water-soluble polymer compound (B) having an alcoholic hydroxyl group; and
a solvent (C) containing an organic solvent having a surface tension of at most about 30 mN/m.

2. The diffusing agent composition according to claim 1 wherein the impurity-diffusing component (A) contains a compound of a group III element.

3. The diffusing agent composition according to claim 1 wherein the water-soluble polymer compound (B) has a saponification degree of at least about 90 mol %.

4. The diffusing agent composition according to claim 1 wherein the water-soluble polymer compound (B) is polyvinyl alcohol.

5. The diffusing agent composition according to claim 1 wherein the solvent (C) contains the organic solvent with a weight percent of at least about 30 percent based on the total weight of the composition.

6. The diffusing agent composition according to claim 1 further comprising a water-soluble monomer (D) having a hydroxyl group.

7. A method of forming an impurity diffusion layer comprising:
forming a pattern by discharging the diffusing agent composition according to claim 1 containing a P-type impurity-diffusing component (A) onto an N-type semiconductor substrate by an ink-jet method; and
diffusing the impurity-diffusing component (A) contained in the diffusing agent composition into the semiconductor substrate.

8. A solar battery comprising a semiconductor substrate in which an impurity diffusion layer is formed by the method of forming an impurity diffusion layer according to claim 7.
